(19) United States
(12) Patent Application Publication
(10) Pub. No.: US 2014/0352144 A1
(43) Pub. Date: Dec. 4, 2014

(54) METHODS FOR IMPROVING ELECTRICAL ISOLATION OF PATTERNED TRANSPARENT CONDUCTIVE FILMS

(71) Applicant: Carestream Health, Inc., Rochester, NY (US)

(72) Inventors: Robert J. Monson, Roseville, MN (US); Andrew T. Fried, Saint Paul, MN (US); Eric L. Granstrom, Andover, MN (US)

(73) Assignee: Carestream Health, Inc., Rochester, NY (US)

(21) Appl. No.: 14/272,878

(22) Filed: May 8, 2014

Related U.S. Application Data
(60) Provisional application No. 61/830,202, filed on Jun. 3, 2013.

(51) Int. Cl. H05K 3/10

(52) U.S. Cl. CPC H05K 3/10; H05K 2203/0502; H05K 2203/105; Y10S 977/762; B82Y 99/00
USPC 29/850; 977/762

(57) ABSTRACT

Claimed methods reduce leakage currents in transparent conductive films comprising conductive nanostructures without substantially impairing the films' optical properties or physical integrity. Imposition of electrical stimuli to separate conductive regions leads to reduced conductivity of the intervening lesser conductive regions.

### CROSS REFERENCE TO RELATED APPLICATIONS

This application claims the benefit of U.S. Provisional Application No. 61/830,202, filed Jun. 3, 2013, entitled METHODS FOR IMPROVING ELECTRICAL ISOLATION OF PATTERNED TRANSPARENT CONDUCTIVE FILMS, which is hereby incorporated by reference in its entirety.

### BACKGROUND

Transparent conductive films are used in electronic applications such as touch screen sensors for portable electronic devices. Transparent conductive films comprising silver nanowires are particularly well suited for such applications because of their flexibility, high conductivity, and high optical transparency.

For many electronic applications, such transparent conductive films are patterned in order to provide high conductivity regions separated by low conductivity regions. In many cases, it is important that the conductivity of the low conductivity regions be minimized, in order to reduce leakage currents between the high conductivity regions. For example, excessive leakage currents in capacitive touch screen applications can reduce sensors' sensitivity to the presence of a person's skin.

U.S. Pat. No. 5,090,121 to Gaddis discloses an apparatus and methods for forming circuit patterns in a circuit board comprising a conductive surface, where portions of the conductive surface are removed by applying a voltage between an electrode configured as a plotter pen and the conductive surface of the circuit board.

U.S. Pat. No. 5,223,687 to Yuasa et al. discloses methods of patterning conductive films by contacting a metal electrode with the surface of the film and applying a voltage of 5 to 60 volts between the electrode and film, resulting in the removal of an area of the conductive film

U.S. Pat. No. 7,648,906 to Takei et al. discloses an apparatus and methods for forming grooves in a conductive thin film on an insulating substrate by applying a voltage between an electrode and the conductive thin film to form grooves passing through the thickness of the conductive thin film to expose the surface of the insulating substrate.

### SUMMARY

Transparent conductive films can be patterned to form low conductivity regions by use of such methods as chemical etching or laser patterning. However, the resulting low conductivity regions often suffer from spatial inhomogeneity in their conductivity, with some portions exhibiting higher conductivity than desired. Such higher conductivity portions can lead to significant leakage current between adjacent high conductivity regions, leading to decreased performance in devices such as capacitive touch panels.

Where such patterned transparent conductive films comprise conductive nanostructures, such as metal nanowires, we have discovered methods to correct and decrease the conductivity of higher conductivity portions of such low conductivity regions without substantially impairing the films' optical properties or physical integrity. The resulting films exhibit improved performance in end-use applications, such as capacitive touch screen devices. At least some embodiments provide methods comprising providing a transparent conductive film comprising at least one first region exhibiting a first conductivity, at least one second region exhibiting a second conductivity, the at least one second region not being in direct contact with the at least one first region, and at least one third region contacting the at least one first region and the at least one second region, the at least one third region comprising at least one first metal nanowire and exhibiting a third conductivity less than both the first conductivity and the second conductivity; and imposing a first electrical stimulus for a first duration between the at least one first region and the at least one second region, where, after imposition of the first electrical stimulus for the first duration, the at least one third region exhibits a fourth conductivity less than the third conductivity.

At least some embodiments provide methods comprising providing a transparent conductive film comprising at least one first region exhibiting a first conductivity, at least one second region exhibiting a second conductivity, at least one third region between the at least one first region and the at least one second region, the at least one third region comprising at least one first conductive nanostructure and exhibiting a third conductivity different from either the first conductivity and the second conductivity; and imposing a first electrical stimulus for a first duration between the at least one first region and the at least one second region, wherein, after imposition of the first electrical stimulus for the first duration, the at least one third region exhibits a fourth conductivity less than the third conductivity. In some embodiments, the at least one first conductive nanostructure may comprise at least one metal nanowire.

Some such methods further comprise, prior to imposing the first electrical stimulus, imposing a second electrical stimulus for second duration between the at least one first region and the at least one second region, where, after imposition of the second stimulus for the second duration, the at least one third region exhibits a fifth conductivity that is greater than a predetermined target conductivity. Such a second electrical stimulus may, in some cases, be smaller in magnitude than the first electrical stimulus. Such a second duration may, in some cases, be shorter than the first duration. In other cases, the second electrical stimulus may be smaller in magnitude than the first electrical stimulus, and the second duration may also be shorter than the first duration. In still other cases, the second electrical stimulus may have the same magnitude as the first electrical stimulus, the second duration may be the same as the first duration, or both.

In any of the above embodiments, the at least one first region may, in some cases, comprise at least one second nanostructure, or, in other cases, the at least one second region may comprise at least one third nanostructure. In still other cases, the at least one first region comprises at least one second nanostructure and the at least one second region comprises at least one third nanostructure. Such nanostructures may, in some cases, comprise conductive nanostructures, such as, for example, metal nanowires.

In any of the above embodiments, one or more of the at least one first nanostructure, the at least one second nanostructure, or the at least one third nanostructure may comprise at least one silver nanowire. In some cases, all of the nanostructures are silver nanowires.

In any of the above embodiments, prior to imposition of the first electrical stimulus for the first duration, the at least one third region may exhibit a preexisting set of optical properties, and after the imposition of the first electrical stimulus for the first duration, the at least one third region may exhibit a consequent set of optical properties, where the preexisting set of optical properties and the consequent set of optical properties are substantially identical. Such a preexisting set of optical properties may comprise one or more of a preexisting total light transmission, a preexisting reflectance value, a preexisting spectral value, a preexisting haze, a preexisting L* value, a preexisting a* value, or a preexisting b* value. Such a consequent set of optical properties may comprise one or more of a consequent total light transmission, a consequent reflectance value, a consequent spectral value, a consequent haze, a consequent L* value, a consequent a* value, or a consequent b* value.

In any of the above embodiments, imposing a first electrical stimulus for a first duration between the at least one first region and the at least one second region may be performed so no gap forms in the at least one third region that may be detected with the unaided eye.

In any of the above embodiments, the first electrical stimulus may comprise a current. In any of the above embodiments, the first electrical stimulus may comprise a voltage. Without wishing to be bound by theory, in any of the above embodiments, the first electrical stimulus may cause a change in third conductivity by changing the conductivity of the at least one first nanostructure; or the first electrical stimulus may cause a change in the third conductivity by changing the phase of the at least one first nanostructure; or the first electrical stimulus may cause a change in the third conductivity by changing the relative positions of nanostructures, resulting in a decrease in number or quality of electrical connections among the nanostructures.

In any of the above embodiments, imposing the first electrical stimulus between the at least one first region and the at least one second region may comprise electrically connecting a first terminal of at least one direct current power source to the at least one first region and a second terminal of the at least one direct current power source to the at least one second region. Such direct current power sources may, in some cases, comprise one or more of at least one electrochemical cell, at least one rectifier, at least one capacitor, at least one solar cell, or at least one fuel cell.

In any of the above embodiments, imposing the first electrical stimulus between the at least one first region and the at least one second region may comprise electrically connecting a first terminal of at least one alternating current power source to the at least one first region and a second terminal of the at least one alternating current power source to the at least one second region. Such alternating current power sources may, in some cases, comprise one or more of at least one generator, at least one alternator, at least one inverter, or at least one transformer.

In any of the above embodiments, imposing the first electrical stimulus between the at least one first region and the at least one second region may comprise electrically connecting a first terminal of at least one pulsed current power source to the at least one first region and a second terminal of the at least one pulsed current power source to the at least one second region. Such pulsed current power source may, in some cases, comprise one or more of at least one pulse generator, at least one waveform generator, at least one network comprising at least one resistor and at least one capacitor, or at least one active circuit.

These embodiments and other variations and modifications may be better understood from the description, examples, and exemplary embodiments that follow. Any embodiments provided are given only by way of illustrative example. Other desirable objectives and advantages in inherently achieved may occur of become apparent to those skilled in the art.

### DESCRIPTION

All publications, patents, and patent documents referred to in this document are incorporated by reference herein in their entirety, as though individually incorporated by reference.

U.S. Provisional Application No. 61/830,202, filed Jun. 3, 2013, entitled METHODS FOR IMPROVING ELECTRICAL ISOLATION OF PATTERNED TRANSPARENT CONDUCTIVE FILMS, is hereby incorporated by reference in its entirety.

### Introduction

Many common methods of patterning transparent conductive films can produce patterned low conductivity regions exhibiting spatially inhomogeneous conductivities. Where such patterned transparent conductive films comprise nanowires, we have discovered that imposition of electrical potential methods across such low conductivity regions can further decrease their conductivity without substantially impairing the films' optical properties or physical integrity. The resulting films exhibit improved performance in end-use applications, such as capacitive touch screen devices.

The methods of the present application differ from known methods of electrically patterning conductive films, such as those disclosed in U.S. Pat. No. 5,090,121 to Gaddis, U.S. Pat. No. 5,223,687 to Yuasa et al., and U.S. Pat. No. 7,648,906 to Takei et al. In these patterning methods, electricity is used to remove the entire thickness of the conductive film that lies under the path of an electrode passing over the surface of the conductive film. By contrast, the methods of the present application do not make use of electrodes passing over the surface of the conductive film, but rather make use of conductive regions internal to the conductive film. The methods of the present application also limit the magnitude and duration of applied electrical stimuli. These differences allow reduction in the conductivity of low conductivity regions of the transparent conductive film without substantially affecting the film's optical properties or physical integrity.

### Low and High Conductivity Regions of Transparent Conductive Film

Transparent conductive films comprising conductive structures, such as conductive microstructures or conductive nanostructures, are known. Microstructures and nanostructures are defined according to the length of their shortest dimensions. The shortest dimension of the nanostructure is sized between 1 nm and 100 nm. The shortest dimension of the microstructure is sized between 0.1 μm to 100 μm. In some embodiments, the conductive nanostructures may comprise, for example, metal nanowires, carbon nanotubes, metal meshes, transparent conductive oxide, and graphene. Metal nanowires may include, for example, silver nanowires. Exemplary transparent conductive films comprising silver nanowires and methods for preparing them are disclosed in US patent application publication 2012/0107600, entitled “TRANSPARENT CONDUCTIVE FILM COMPRISING CELLULOSE ESTERS,” which is hereby incorporated by reference in its entirety.

Such transparent conductive films exhibit low surface bulk or sheet resistivities, often below about 100 ohms/sq prior to patterning. The transparent conductive films may be patterned to introduce low conductivity regions within the transparent conductive film, leaving the remaining regions as high conductivity regions. Patterning methods are known in the art, such as chemical etching, screen printed mask, screen printed etching, photolithography, or laser patterning. In some cases, the fact that patterning has been performed may be obscured by making the high conductivity regions and low conductivity regions have similar optical properties, rendering the patterned film suitable for various end-use applications. Maintenance of the film's optical properties in subsequent processing, such as the methods of the present application, can therefore be important for fitness-for-use in such applications.

After patterning the transparent conductive film, the resulting low conductivity regions often suffer from spatial inhomogeneity in their conductivity, with some portions exhibiting higher conductivity than desired. Such higher conductivity portions can lead to significant leakage current between adjacent high conductivity regions when used in electronic applications, leading to decreased performance in devices such as capacitive touch panels. Without wishing to be bound by theory, it is believed that the higher conductivity portions may retain conductive nanostructures that are still able to provide electrical conductivity through the low conductivity region to neighboring high conductivity regions of the transparent conductive film.

### Imposing Electrical Stimuli and Power Sources

In some embodiments, an electrical stimulus is applied to at least two higher conductive regions that are not in direct contact, but which all contact at least one lower conductive region. Without wishing to be bound by theory, it is believed that in so doing, localized Ohmic heating in the higher conductivity portions of the at least one lower conductivity region disrupts the conductive nanostructures therein. The electrical stimulus may, in some cases, change the phase of the nanostructure, such as by localized melting, vaporization or other modification or conductivity of the nanostructure to decrease the conductivity or conductance of such portions. The electrical stimulus may, in other cases, cause a change in conductivity by changing the relative positions of nanostructures, resulting in a decrease in number or quality of electrical connections among nano structures. By limiting the magnitude and duration of the applied electrical stimulus, the optical properties and physical integrity of the transparent conductive film may, in some cases, be left substantially unaltered.

The electrical stimulus may be, such as, for example, an electric current or an electrical potential difference, such as voltage. In some embodiments, the electrical stimulus is a current. An electrical potential difference, such as a voltage, may be produced by an electric current through a magnetic field. The electrical stimulus may be developed by either one or more direct current power sources, one or more alternating current power sources, or one or more pulsed current power sources. Such direct current power sources may, in some cases, comprise one or more of at least one electrochemical cell, at least one rectifier, at least one capacitor, at least one solar cell, or at least one fuel cell. Such alternating current power sources may, in some cases, comprise one or more of at least one generator, at least one alternator, at least one inverter, or at least one transformer. Such pulsed current power sources may, in some cases, comprise one or more of at least one pulse generator, at least one waveform generator, at least one network comprising at least one resistor and at least one capacitor, or at least one active circuit. In some embodiments, the electrical stimulus is applied to the conductive film by directing the power source at the conductive film without contacting the conductive film. The application of a current source may produce an electrical potential difference, such as a voltage, within the conductive film. In some embodiments, an electrical potential difference, such as a voltage, is directly applied to the film by static electric fields. In some embodiments, an electrical potential difference, such as a voltage, is directly applied to the film by time-varying magnetic fields.

The electrical stimulus may vary in magnitude during the duration of its application. In some cases, a series of pulses might be used, instead of a single discrete pulse. The pulse duration produced by such pulsed current power source may, in some cases, be of duration less than 100 milliseconds, or less than 100 microseconds, or less than 100 nanoseconds, or less than 100 picoseconds.

In some embodiments, electrical stimulus is applied directly to the conductive film. In other embodiments, electrical stimulus is applied to a chip, such as a sensor chip, that has been assembled with the conductive film. When the electrical stimulus, such as a current, is applied to the conductive film or chip, the current may flow parallel to the plane of the conductive film or chip along the electrical test points within the conductive film or chip.

### Optical Properties

In some embodiments, prior to imposition of the electrical stimulus to the high conductivity regions, the lower conductivity regions may exhibit a preexisting set of optical properties, and after the imposition of the electrical stimulus, these regions may exhibit a consequent set of optical properties that are substantially identical to the preexisting set of optical properties. For the purpose of this application, the term “substantially identical” indicates differences that are not discernible to the unaided eye.

Such a preexisting set of optical properties may, for example, comprise one or more of a preexisting total light transmission, a preexisting haze, a preexisting reflectance value, a preexisting spectral value, a preexisting L* value, a preexisting a* value, or a preexisting b* value. Such a consequent set of optical properties may, for example, comprise one or more of a consequent total light transmission, a consequent haze, a consequent reflectance value, a consequent spectral value, a consequent L* value, a consequent a* value, or a consequent b* value. For the purpose of this application, “substantially similar optical appearance” indicates that differences in total light transmission, haze, L*, a*, and b* are not discernible to the unaided eye. The L* value, a* value, and b* value are part of the Commission Internationale de l'Eclairage (CIE) system of describing the color of an object.

### EXEMPLARY EMBODIMENTS

U.S. Provisional Application No. 61/830,202, filed Jun. 3, 2013, entitled METHODS FOR IMPROVING ELECTRICAL ISOLATION OF PATTERNED TRANSPARENT CONDUCTIVE FILMS, which is hereby incorporated by reference in its entirety, disclosed the following 29 non-limiting exemplary embodiments:

A. A method comprising:

providing a transparent conductive film comprising:
at least one first region exhibiting a first conductivity,
at least one second region exhibiting a second conductivity, the at least one second region not being in direct contact with the at least one first region, and
at least one third region contacting the at least one first region and the at least one second region, the at least one third region comprising at least one first conductive nanostructure and exhibiting a third conductivity less than both the first conductivity and the second conductivity; and

imposing a first electrical stimulus for a first duration between the at least one first region and the at least one second region,

wherein, after imposition of the first electrical stimulus for the first duration, the at least one third region exhibits a fourth conductivity less than the third conductivity.

B. The method according to embodiment A, further comprising:

prior to imposing the first electrical stimulus, imposing a second electrical stimulus for second duration between the at least one first region and the at least one second region,

wherein, after imposition of the second stimulus for the second duration, the at least one third region exhibits a fifth conductivity that is greater than a predetermined target conductivity.

C. The method according to embodiment B, wherein the second electrical stimulus is smaller in magnitude than the first electrical stimulus.
D. The method according to embodiment B, wherein the second duration is shorter than the first duration.
E. The method according to embodiment B, wherein the second electrical stimulus is smaller in magnitude than the first electrical stimulus, and the second duration is shorter than the first duration.
F. The method according to any of embodiments A-E, wherein the first conductive nanostructure comprises at least one first metal nanowire, and wherein the at least one first region comprises at least one second metal nanowire.
G. The method according to any of embodiments A-F, wherein the first conductive nanostructure comprises at least one first metal nanowire, and wherein the at least one second region comprises at least one third metal nanowire.
H. The method according to any of embodiments A-G, wherein at least one of the at least one first metal nanowire, the at least one second metal nanowire, or the at least one third metal nanowire comprises at least one silver nanowire.
J. The method according to any of embodiments A-H,

wherein prior to imposition of the first electrical stimulus for the first duration, the at least one third region exhibited a preexisting set of optical properties, and after the imposition of the first electrical stimulus for the first duration, the at least one third region exhibited a consequent set of optical properties, and

further wherein the preexisting set of optical properties and the consequent set of optical properties are substantially identical.

K. The method according to embodiment J, wherein the preexisting set of optical properties comprises a preexisting total light transmission and the consequent set of optical properties comprises a consequent total light transmission that is substantially identical to the preexisting total light transmission.
L. The method according to embodiment J, wherein the preexisting set of optical properties comprises a preexisting haze and the consequent set of optical properties comprises a consequent haze that is substantially identical to the preexisting haze.
M. The method according to embodiment J, wherein the preexisting set of optical properties comprises a preexisting L* value and the consequent set of optical properties comprises a consequent L* value that is substantially identical to the preexisting L* value.
N. The method according to embodiment J, wherein the preexisting set of optical properties comprises a preexisting a* value and the consequent set of optical properties comprises a consequent a* value that is substantially identical to the preexisting a* value.
P. The method according to embodiment J, wherein the preexisting set of optical properties comprises a preexisting b* value and the consequent set of optical properties comprises a consequent b* value that is substantially identical to the preexisting b* value.
Q. The method according to any of embodiments A-P, wherein imposing the first electrical stimulus for the first duration between the at least one first region and the at least one second region does not form a gap in the at least one third region that is detectable with the unaided eye.
R. The method according to any of embodiments A-Q, wherein imposing the first electrical stimulus between the at least one first region and the at least one second region comprises electrically connecting a first terminal of at least one direct current power source to the at least one first region and a second terminal of the at least one direct current power source to the at least one second region.
S. The method according to embodiment R, wherein the at least one direct current power source comprises one or more of at least one electrochemical cell, at least one rectifier, at least one capacitor, at least one solar cell, or at least one fuel cell.
T. The method according to any of embodiments A-S, wherein imposing the first electrical stimulus between the at least one first region and the at least one second region comprises electrically connecting a first terminal of at least one alternating current power source to the at least one first region and a second terminal of the at least one alternating current power source to the at least one second region.
U. The method according to embodiment T, wherein the at least one alternating current power source comprises one or more of at least one generator, at least one alternator, at least one inverter, or at least one transformer.
V. The method according to any of embodiments A-S, wherein imposing the first electrical stimulus between the at least one first region and the at least one second region comprises electrically connecting a first terminal of at least one pulsed current power source to the at least one first region and a second terminal of the at least one pulsed current power source to the at least one second region.
W. The method according to embodiment V, wherein the at least one pulsed current power source comprises one or more of at least one pulse generator, at least one waveform generator, at least one network comprising at least one resistor and at least one capacitor, or at least one active circuit.
X. The method according to any of embodiments A-W, wherein the at least one first conductive nanostructure comprises a metal nanowire.
Y. The method according to any of embodiments A-X, wherein the first electrical stimulus causes the third conductivity by changing the conductivity of the at least one first conductive nanostructure.
Z. The method according to any of embodiments A-Y, wherein the first electrical stimulus causes the third conductivity by changing the phase of the at least one first conductive nanostructure.
AA. The method according to any of embodiments A-Z, wherein the first electrical stimulus causes the third conductivity by changing the position of the at least one first conductive nanostructure.
AB. The method according to any of embodiments A-AA, wherein the first electrical stimulus comprises a current.
AC. The method according to any of embodiments A-AB, wherein the first electrical stimulus comprises a voltage.
AD. The method according to embodiment J, wherein the preexisting set of optical properties comprises a preexisting reflectance value and the consequent set of optical properties comprises a consequent reflectance value that is substantially identical to the preexisting reflectance value.
AE. The method according to embodiment J, wherein the preexisting set of optical properties comprises a preexisting spectral value and the consequent set of optical properties comprises a consequent spectral value that is substantially identical to the preexisting spectral value.

### EXAMPLES

### Example 1 (Prophetic)

A transparent conductive film comprising silver nanowires is prepared according to the materials and methods disclosed in US patent application publication 2012/0107600, entitled “TRANSPARENT CONDUCTIVE FILM COMPRISING CELLULOSE ESTERS,” which is hereby incorporated by reference in its entirety. The surface of the transparent conductive film is patterned to provide low conductivity regions that separate adjacent high conductivity regions. Silver conductive paste is used to electrically connect each of the high conductivity regions to electrical test points. After the paste dries, resistance measurements are taken by applying the test leads of an ohmmeter to successive pairs of electrical test points. Measured conductivities are calculated by taking the reciprocal of each of the measured resistances.

Each of the measured conductivities is compared to a target conductivity. For each measured conductivity that is higher than the target conductivity, the two terminals of a direct current power supply are attached to the corresponding test points and an electrical potential difference is applied for a first duration. Conductivities are then measured across these test points and are found to be no greater than the target conductivity. The optical appearance of the electrically treated low conductivity regions is substantially similar to the appearance of untreated low conductivity regions.

### Example 2 (Prophetic)

A patterned transparent conductive film is prepared as in Example 1. Conductivities of the low conductivity regions are measured as in Example 1. The measured conductivity of one low conductivity region was higher than the target conductivity. Two terminals of a direct current power supply are attached to the corresponding test points and a first electrical potential difference is applied for a first duration. The conductivity of the region is measured and found not to be different from the original measurement.

A second electrical potential difference greater than the first electrical potential difference is applied for the same duration as before by attaching the two terminals of the direct current power supply to the test points. The conductivity of the region is measured and found to be no greater than the target conductivity. The optical appearance of the electrically treated low conductivity region is substantially similar to the appearance of untreated low conductivity regions.

### Example 3 (Prophetic)

A patterned transparent conductive film is prepared as in Example 1. Conductivities of the low conductivity regions are measured as in Example 1. The measured conductivity of one low conductivity region was higher than the target conductivity. Two terminals of a direct current power supply are attached to the corresponding test points and a first electrical potential difference is applied for a first duration. The conductivity of the region is measured and found not to be different from the original measurement.

An electrical potential difference equal to the first electrical potential difference is applied for a duration longer than the first duration by attaching the two terminals of the direct current power supply to the test points. The conductivity of the region is measured and found to be no greater than the target conductivity. The optical appearance of the electrically treated low conductivity region is substantially similar to the appearance of untreated low conductivity regions.

### Example 4 (Prophetic)

A patterned transparent conductive film is prepared as in Example 1. Conductivities of the low conductivity regions are measured as in Example 1. The measured conductivity of one low conductivity region was higher than the target conductivity. Two terminals of a direct current power supply are attached to the corresponding test points and a first electrical potential difference is applied for a first duration. The conductivity of the region is measured and found to be less than the original measurement, but greater than the target conductivity.

An electrical potential difference equal to the first electrical potential difference is applied for a duration equal to the first duration by attaching the two terminals of the direct current power supply to the test points. The conductivity of the region is measured and found to be no greater than the target conductivity. The optical appearance of the electrically treated low conductivity region is substantially similar to the appearance of untreated low conductivity regions.

### Example 5 (Prophetic)

A patterned transparent conductive film is prepared as in Example 1. Conductivities of the low conductivity regions are measured as in Example 1. The measured conductivity of one low conductivity region was higher than the target conductivity. Two terminals of a direct current power supply are attached to the corresponding test points and a first electrical potential difference is applied for a first duration. The conductivity of the region is measured and found to be less than the original measurement, but greater than the target conductivity.

An electrical potential difference equal to the first electrical potential difference is applied for a duration equal to the first duration by attaching the two terminals of the direct current power supply to the test points. The conductivity of the region is measured and found to be less than the previous measurements, but greater than the target conductivity. An electrical potential difference equal to the first electrical potential difference is applied for a duration equal to the first duration by attaching the two terminals of the direct current power supply to the test points. The conductivity of the region is measured and found to be no greater than the target conductivity. The optical appearance of the electrically treated low conductivity region is substantially similar to the appearance of untreated low conductivity regions.

The invention has been described in detail with reference to particular embodiments, but it will be understood that variations and modifications can be effected within the spirit and scope of the invention. The presently disclosed embodiments are therefore considered in all respects to be illustrative and not restrictive. The scope of the invention is indicated by the claims, and all changes that come within the meaning and range of equivalents thereof are intended to be embraced therein.

What is claimed:

1. A method comprising:
providing a transparent conductive film comprising:
at least one first region exhibiting a first conductivity,
at least one second region exhibiting a second conductivity, the at least one second region not being in direct contact with the at least one first region, and
at least one third region contacting the at least one first region and the at least one second region, the at least one third region comprising at least one first conductive nanostructure and exhibiting a third conductivity less than both the first conductivity and the second conductivity; and
imposing a first electrical stimulus for a first duration between the at least one first region and the at least one second region,
wherein, after imposition of the first electrical stimulus for the first duration, the at least one third region exhibits a fourth conductivity less than the third conductivity.

2. The method according to claim 1, wherein the first conductive nanostructure comprises at least one first metal nanowire.

3. The method according to claim 2, wherein the at least one first region or the at least one second region comprises at least one second metal nanowire.

4. The method according to claim 3, wherein at least one of the at least one first metal nanowire or the at least one second metal nanowire comprises at least one silver nanowire.

5. The method according to claim 2, wherein the at least one first metal nanowire comprises at least one silver nanowire.

6. The method according to claim 1,
wherein prior to imposition of the first electrical stimulus for the first duration, the at least one third region exhibited a preexisting set of optical properties, and after the imposition of the first electrical stimulus for the first duration, the at least one third region exhibited a consequent set of optical properties, and
further wherein the preexisting set of optical properties and the consequent set of optical properties are substantially identical.

7. The method according to claim 5, wherein the preexisting set of optical properties comprises a preexisting total light transmission and the consequent set of optical properties comprises a consequent total light transmission that is substantially identical to the preexisting total light transmission.

8. The method according to claim 5, wherein the preexisting set of optical properties comprises a preexisting haze and the consequent set of optical properties comprises a consequent haze that is substantially identical to the preexisting haze.

9. The method according to claim 5, wherein the preexisting set of optical properties comprises a preexisting L* value and the consequent set of optical properties comprises a consequent L* value that is substantially identical to the preexisting L* value.

10. The method according to claim 5, wherein the preexisting set of optical properties comprises a preexisting a* value and the consequent set of optical properties comprises a consequent a* value that is substantially identical to the preexisting a* value.

11. The method according to claim 5, wherein the preexisting set of optical properties comprises a preexisting b* value and the consequent set of optical properties comprises a consequent b* value that is substantially identical to the preexisting b* value.

12. The method according to claim 5, wherein the preexisting set of optical properties comprises a preexisting reflectance value and the consequent set of optical properties comprises a consequent reflectance value that is substantially identical to the preexisting reflectance value.

13. The method according to claim 5 wherein the preexisting set of optical properties comprises a preexisting spectral value and the consequent set of optical properties comprises a consequent spectral value that is substantially identical to the preexisting spectral value.

14. The method according to claim 1, wherein imposing the first electrical stimulus for the first duration between the at least one first region and the at least one second region does not form a gap in the at least one third region that is detectable with the unaided eye.

15. The method according to claim 1, wherein the first electrical stimulus changes the conductivity of the at least one first conductive nanostructure.

16. The method according to claim 1, wherein the first electrical stimulus changes the phase of the at least one first conductive nanostructure.

17. The method according to any of claim 1, wherein the first electrical stimulus changes the position of the at least one first conductive nanostructure.

18. The method according to claim 1, wherein the first electrical stimulus comprises a current.

19. The method according to claim 1, wherein the first electrical stimulus comprises a voltage.
